(19) United States
(12) Patent Application Publication
(10) Pub. No.: US 2014/0327104 A1
(43) Pub. Date: Nov. 6, 2014

(54) Semiconductor Device with a Super Junction Structure with Compensation Layers and a Dielectric Layer

(71) Applicant: Infineon Technologies Austria AG, Villach (AT)

(72) Inventors: Armin Willmeroth, Augsburg (DE); Stefan Gamerith, Villach (AT); Markus Schmitt, Neubiberg (DE); Bjoern Fischer, Munich (DE)

(21) Appl. No.: 13/874,898

(22) Filed: May 1, 2013

(51) Int. Cl. H01L 29/06

(52) U.S. Cl. CPC H01L 29/0634
USPC 257/493

(57) ABSTRACT

A super junction semiconductor device includes a layered compensation structure with an n-type compensation layer and a p-type compensation layer, a dielectric layer facing the p-type layer, and an intermediate layer interposed between the dielectric layer and the p-type compensation layer. The layered compensation structure and the intermediate layer are provided such that when a reverse blocking voltage is applied between the n-type and p-type compensation layers, holes accelerated in the direction of the dielectric layer have insufficient energy to be absorbed and incorporated into the dielectric material. Since the dielectric layer absorbs and incorporates significantly less holes than without the intermediate layer, the breakdown voltage remains stable over a long operation time.

### BACKGROUND

A semiconductor portion of a super junction FET (field effect transistor) based on a trench concept typically includes complementary doped layers extending in substance parallel to a flow direction of an on-state current flowing in the conductive state in one of the complementary doped layers. In the reverse blocking mode the complementary doped layers are depleted such that a high reverse breakdown voltage can be achieved even at a comparatively high impurity concentration in the doped layer carrying the on-state current. It is desirable to improve long-term stability of characteristic parameters of super junction semiconductor devices.

### SUMMARY

According to an embodiment, a super junction semiconductor device comprises a layered compensation structure with an n-type compensation layer and a p-type compensation layer, a dielectric layer facing the p-type layer, and an intermediate layer interposed between the dielectric layer and the p-type compensation layer. The layered compensation structure and the intermediate layer are provided such that when a reverse blocking voltage is applied between the n-type and p-type compensation layers, holes accelerated in the direction of the dielectric layer have insufficient energy to be absorbed and incorporated into the dielectric material.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1 is a schematic cross-sectional view of a portion of a semiconductor device in accordance with an embodiment providing an intermediate layer.

FIG. 2A is a schematic cross-sectional view of a portion of a compensation structure according to a comparative example for illustrating effects of the present embodiments.

FIG. 2B is a schematic diagram illustrating a lateral electric field profile in the compensation structure of FIG. 2A.

FIG. 3A is a schematic cross-sectional view of a portion of a compensation structure according to an embodiment providing an intrinsic intermediate layer.

FIG. 3B is a schematic diagram illustrating a lateral electric field profile in the compensation structure of FIG. 3A.

FIG. 4A is a schematic cross-sectional view of a transistor portion of semiconductor devices in accordance with embodiments providing planar transistors with gate electrodes outside a semiconductor portion.

FIG. 4B is a schematic cross-sectional view of a transistor portion of semiconductor devices in accordance with embodiments providing vertical transistors with buried gate electrodes and with source zones provided in the vertical projection of compensation trenches.

FIG. 4C is a schematic cross-sectional view of a transistor portion of semiconductor devices in accordance with embodiments providing vertical transistors with buried gate electrodes and with source zones provided in semiconductor mesas between compensation trenches.

FIG. 5A is a schematic cross-sectional view of a portion of a semiconductor device in accordance with an embodiment providing an n-type intermediate layer and an intrinsic layer interposed between the p-type and the n-type compensation layers.

FIG. 5B shows a portion of the compensation structure of FIG. 5A at a larger scale.

FIG. 5C is a schematic diagram illustrating a lateral electric field profile in the compensation structure of FIG. 5B.

FIG. 6 is a schematic cross-sectional view of a portion of an IGFET in accordance with an embodiment providing a graded p-type intermediate layer.

FIG. 7 is a schematic cross-sectional view of a portion of an IGBT in accordance with another embodiment.

FIG. 8 is a schematic cross-sectional view of a portion of a semiconductor diode in accordance with a further embodiment.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

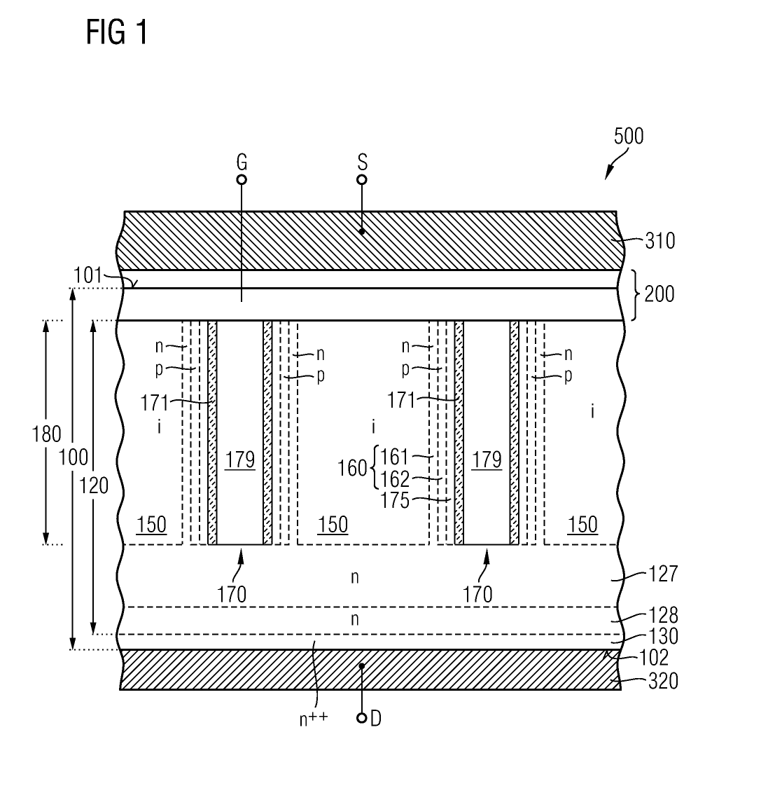

FIG. 1 shows a super junction semiconductor device 500 with a semiconductor portion 100 having a first surface 101 and a second surface 102 parallel to the first surface 101. The semiconductor portion 100 is provided from a single-crystalline semiconductor material, for example silicon Si, silicon carbide SiC, germanium Ge, a silicon germanium crystal SiGe, gallium nitride GaN or gallium arsenide GaAs. A distance between the first and second surfaces 101, 102 is at least 40 μm, for example at least 175 μm. The semiconductor portion 100 may have a rectangular shape with an edge length in the range of several millimeters or a circular shape with a diameter of several millimeters. The normal to the first and second surfaces 101, 102 defines a vertical direction and directions orthogonal to the normal direction are lateral directions.

The semiconductor portion 100 may include an impurity layer 130 of a first conductivity type. The impurity layer 130 may extend along a complete cross-sectional plane of the semiconductor portion 100 parallel to the second surface 102. In case the semiconductor device 500 is an IGFET (insulated gate field effect transistor), the impurity layer 130 directly adjoins the second surface 102 and a mean net impurity concentration in the impurity layer 130 is comparatively high, e.g. at least 5×10¹⁸ cm⁻³. In case the semiconductor device 500 is an IGBT (insulated gate bipolar transistor), a collector layer of a second conductivity type, which is the opposite of the first conductivity type, is arranged between the impurity layer 130 and the second surface 102 and the mean net impurity concentration in the impurity layer 130 may be between 5×10¹² and 5×10¹⁶ cm⁻³, by way of example.

The semiconductor portion 100 further includes a drift zone 120 between the first surface 101 and the impurity layer 130.

In the drift zone 120 compensation trenches 170 extend along the vertical direction with sections of the semiconductor portion 100 between the compensation trenches 170 forming mesa regions 150. The mesa regions 150 may be intrinsic, homogeneously p- or n-doped or the impurity concentration may change gradually or in steps from p-loaded to n-loaded or vice-versa.

The drift zone 120 further includes a super junction structure 180 and may include a pedestal layer 128 of the first conductivity type between the super junction structure 180 and the impurity layer 130. According to other embodiments, the super junction structure 180 may directly adjoin the impurity layer 130.

According to the illustrated embodiment, the semiconductor portion further includes a contiguous drift layer 127 between the super junction structure 180 and the pedestal layer 128. The pedestal layer 128 may be effective as a field stop layer having a mean net impurity concentration that is higher than in the drift layer 127 and lower than in the impurity layer 130. The mean net impurity concentration in the pedestal layer 128 may be at least 10 times the mean net impurity concentration in the drift layer 127 and at most a tenth of the mean net impurity concentration in the impurity layer 130. For example, the mean net impurity concentration in a pedestal layer 128 effective as a field stop may be at least 5×10¹⁶ cm⁻³ and at most 5×10¹⁷ cm⁻³.

According to other embodiments, the pedestal layer 128 is effective as a buffer region and has a mean net impurity concentration lower than the mean net impurity concentration in the drift layer 127. For example, the mean net impurity concentration in the drift layer 127 is at least twice the mean net impurity concentration in a pedestal layer 128 effective as buffer region.

The super junction structure 180 is based on a layered compensation structure 160, which includes at least one n-type compensation layer 161 and at least one p-type compensation layer 162. The compensation structure 160 may include further n-type layers, p-type layers or intrinsic layers, for example an intrinsic layer interposed between the p-type and n-type compensation layers 161, 162. Interfaces between the compensation layers 161, 162 are parallel or approximately parallel to an interface between the compensation structure 160 and the material of the semiconductor portion 100.

According to the illustrated embodiment, the compensation structure 160 lines exclusively straight portions of mesa sidewalls of the mesa regions 150, wherein the straight portions are perpendicular or tilted to the first surface 101. According to other embodiments the compensation structure 160 may also line bottom portions of the compensation trenches 170 connecting neighboring mesa sidewalls, respectively, wherein the bottom portions may be curved or approximately planar.

The compensation layers 161, 162 are at least approximately conformal layers, each layer having an approximately uniform thickness. The compensation layers 161, 162 may be single crystalline semiconductor layers grown by epitaxy, with the crystal lattice growing in registry with a crystal lattice of the single crystalline semiconductor material of the semiconductor portion 100 or may be formed by re-crystallization of deposited semiconductor material, for example polycrystalline silicon, using a locally effective laser heating treatment. The first and second compensation layers 161, 162 may be in-situ doped during epitaxial growth. According to other embodiments, impurities of the first and second conductivity type may be introduced into the respective layers e.g. by using tilted implants. The first and second compensation layers 161, 162 are in substance charge balanced and the lateral area densities deviate from each other by at most 10%. One type of the compensations layers 161, 162, i.e. either the p-type or the n-type layer(s), carry the on-state current in the conductive state.

The compensation trenches 170 may be parallel stripes arranged at regular distances. According to other embodiments, the cross-sectional areas of the compensation trenches 170 parallel to the first surface 101 may be circles, ellipsoids, ovals or rectangles, e.g. squares, with or without rounded corners. Accordingly, the mesa regions 150 between the compensation trenches 170 may be stripes or segments of a grid embedding the compensation trenches 170. Accordingly, the cross-sectional areas of the mesa regions 150 parallel to the first surface 101 may be circles, ellipsoids, ovals or rectangles, e.g. squares, with or without rounded corners and the compensation trenches 170 are segments of a grid embedding the mesa regions 150.

The thickness of the n-type compensation layer 161 may be at least 10 nm and at most 250 nm, by way of example. The thickness of the p-type compensation layer 162 may be at least 10 nm and at most 250 nm, by way of example. The compensation layers 161, 162 may have the same thickness or may have different thicknesses. According to an embodiment, the n-type compensation layer 161 has a thickness of 50 nm and the p-type compensation layer 162 a thickness of 50 nm. In a vertical section unit the total amount of impurities in the n-type compensation layer 161 may in substance correspond to the total amount of impurities in the p-type compensation layer 162. For example, both layers 161, 162 may have the same thickness and the same mean net impurity concentration (doping level) of about 2×10¹⁷ cm⁻³.

A dielectric layer 171 faces the p-type compensation layer 162. The dielectric layer 171 may consist of one single layer or may include two or more sub-layers provided from silicon oxide, silicon nitride, siliconoxynitride, an organic dielectric, for example polyimide, or a silicate glass, for example BSG (boron silicate glass), PSG (phosphorus silicate glass), or BPSG (boron phosphorus silicate glass). The dielectric layer 171 and the compensation structure 160 may fill the compensation trenches 170 completely. According to other embodiments, the dielectric layer 171 lines the compensation trench 170 on a surface of the compensation structure 160. A residual space in the compensation trench 170 forms an air gap 179 in a central portion of the compensation trench 170. Other than a complete trench fill, which may induce mechanical strain into the surrounding semiconductor material, the air gap 179 accommodates mechanical strain.

According to another embodiment, the dielectric layer 171 is a native oxide or a combination of a native oxide and a highly non-conformal layer predominantly deposited in a portion of the compensation trench 170 oriented to the first surface 101, bridging the space between the two opposing compensation structures 160 close to the first surface 101 and closing the air gap in the compensation trench 170.

The semiconductor device 500 further includes a control structure 200 adapted to the type of the semiconductor device 500. In case the semiconductor device 500 is a semiconductor diode, the control structure 200 contains an electrode layer of the second conductivity type electrically connected to a corresponding one of the compensation layers 161, 162. For example, the second conductivity type is p-type and the electrode layer is a p-type anode layer connected with the p-type compensation layer 162. According to embodiments referring to IGFETs and IBGTs, the control structure 200 includes field effect transistor structures for controlling a current flow between the first surface 101 and the second surface 102 through the semiconductor portion 100 in response to a signal applied to a gate terminal G. The control structure 200 includes conductive structures, insulating structures and doped regions formed or buried in the semiconductor portion 100 and may include conductive and insulating structures outside the semiconductor portion 100 as well.

A first electrode structure 310 may be electrically connected to the control structure 200 at the side of the first surface 101. The first electrode structure 310 may be electrically coupled to a source terminal S in case the semiconductor device 500 is an IGFET, to an emitter terminal in case the semiconductor device 500 is an IGBT or to an anode terminal in case the semiconductor device 500 is a semiconductor diode.

A second electrode structure 320 directly adjoins the second surface 102 of the semiconductor portion 100. According to embodiments related to semiconductor diodes or IGFETs, the second electrode structure 320 directly adjoins the impurity layer 130. According to embodiments related to IGBTs, a collector layer of the second conductivity type may be formed between the impurity layer 130 and the second electrode structure 320. The second electrode structure 320 may be electrically coupled to a drain terminal D in case the semiconductor device 500 is an IGFET, to a collector terminal in case the semiconductor device 500 is an IGBT or to a cathode terminal in case the semiconductor device 500 is a semiconductor diode.

Each of the first and second electrode structures 310, 320 may consist of or contain, as main constituent(s) aluminum Al, copper Cu, or alloys of aluminum or copper, for example AlSi, AlCu or AlSiCu. According to other embodiments, one or both of the first and second electrode structures 310, 320 may contain one or more layers with nickel Ni, titanium Ti, silver Ag, gold Au, platinum Pt and/or palladium Pd as main constituent(s). For example, at least one of the first and second electrode structures 310, 320 includes two or more sub-layers, at least one of the sub-layers containing one or more of Ni, Ti, Ag, Au, Pt, and Pd as main constituent(s), e.g. a silicide, a nitride and/or an alloy.

The super junction semiconductor device 500 further includes an intermediate layer 175 between the dielectric layer 171 and the compensation structure 160. The intermediate layer 175 directly adjoins both the dielectric layer 171 and the compensation structure 160 and separates the dielectric layer 171 from the p-type layer 162 of the compensation structure 160. Thickness, impurity type and/or impurity concentration gradient in the intermediate layer 175 are provided such that when a reverse blocking voltage close to the nominal breakdown voltage of the semiconductor device 500 is applied between the n-type and p-type compensation layers 161, 162 at least a portion of the intermediate layer 175 directly adjoining the dielectric layer 171 is free or approximately free of a lateral electric field accelerating holes in the lateral direction towards the dielectric layer 171 such that the holes have insufficient energy to be absorbed and incorporated into the dielectric material of the dielectric layer 171 along the interface.

The intermediate layer 175 bars holes from being incorporated into the dielectric layer 171. Stationary charge carriers in the dielectric layer 171, like incorporated holes, may de-tune the nominal compensation between the first and the second compensation layers 161, 162, wherein with increasing de-tuning the vertical electric field gradient becomes steeper and the integral over the vertical field gradient between the first and the second surfaces 101, 102, which gives the nominal breakdown voltage, decreases. As a result, holes incorporated and localized in the dielectric layer 171 reduce the breakdown voltage the semiconductor device 500.

The intermediate layer 175 bars holes from being incorporated into the dielectric layer 171 and therefore improves long term stability of the nominal breakdown voltage.

The intermediate layer 175 may be an intrinsic semiconductor layer, an n-type semiconductor layer or a p-type semiconductor layer with the p-type impurity concentration decreasing to below ten times the intrinsic charge carrier density, e.g. below 1.5×10¹¹ cm⁻³ in Si, in an interface portion directly adjoining the dielectric layer 171. A thickness of the intermediate layer 175 may be at least 5 nm and at most 500 nm.

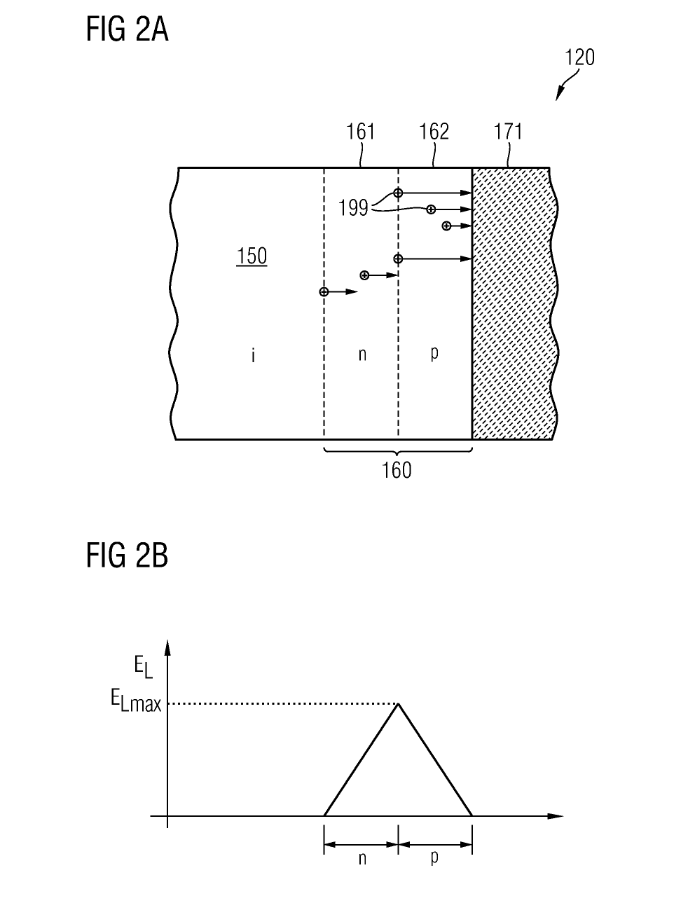

FIGS. 2A and 2B refer to a conventional approach with the compensation structure 160 lining a mesa region 150 and with the p-type compensation layer 162 directly adjoining a dielectric layer 171. When a reverse blocking voltage is applied between the p-type compensation layer 162 and the n-type compensation layer 161, the compensation layers 161, 162 become depleted starting from the vertical pn junction between the n-type compensation layer 161 and the p-type compensation layer 162.

FIG. 2B illustrates the resulting electric field at uniform impurity distributions. In case of an abrupt pn junction with uniform impurity distributions in both the p-type and the n-type compensation layers 161, 162, the lateral electric field E_{L} has a maximum value E_{Lmax} at the pn junction and decreases linearly with increasing distance to the pn junction. The maximum lateral electric field strength E_{Lmax} depends on the impurity concentrations in the compensation layers 161, 162 and the applied reverse blocking voltage. The electric field extends neither into the intrinsic mesa region 150 nor into the dielectric layer 171.

Under certain operation conditions, for example in an avalanche mode, electron hole pairs may be generated in the compensation structure 160. The lateral electric field accelerates holes 199 in the direction of the dielectric layer 171, wherein the acceleration is a function of the lateral electric field strength as indicated by the length of the arrows in FIG. 2A.

In combination with the vertical electric field, the holes accelerated into the direction of the dielectric layer 171 contribute to an electric current flowing in a current filament along the interface between the compensation structure 160 and the dielectric layer 171. The holes in the current filament can be absorbed by and incorporated into the material of the dielectric layer 171. A total charge of the incorporated holes gradually accumulates. The total charge of the accumulated holes adds to the compensation charges in the p-type compensation layer 162, thereby gradually de-tuning the preset compensation between the n-type and the p-type compensation layers 161, 162. For example, at a center-to-center distance (pitch) of 5 μm between neighboring compensation trenches, an area charge density of 2×10¹¹ cm⁻² caused by absorbed holes corresponds to an effective p-type impurity concentration of 8×10¹⁴ cm⁻³ resulting in a significant additional de-tuning of the preset compensation and a gradual reduction of the breakdown voltage.

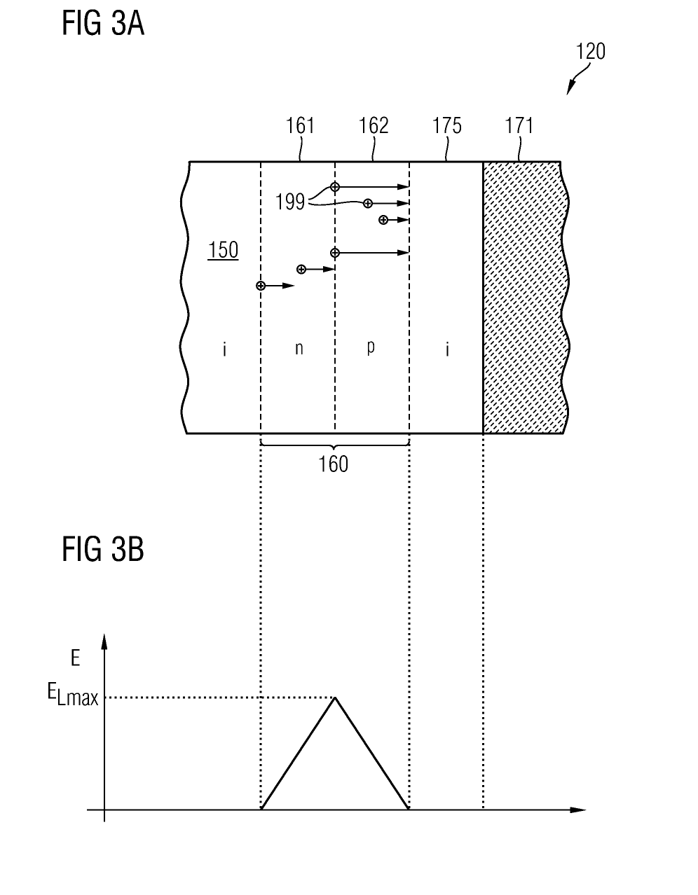

FIGS. 3A and 3B illustrate the effect of an intermediate layer 175, which is assumed to be intrinsic for simplification. The electric field resulting from the depletion of the compensation structure 160 is in substance confined to the compensation structure 160 and does not extend into the intermediate layer 175. In the intermediate layer 175, the electric field strength has only a vertical component, whereas a lateral electric field accelerating holes into the direction of the dielectric layer 171 is almost completely absent. Neither in the avalanche mode nor in the conductive mode does a hole current flow along the interface between the dielectric layer 171 and the intermediate layer 175. The dielectric layer 175 absorbs and incorporates significantly less holes than without the intermediate layer 175. The breakdown voltage remains stable over a longer operation time.

According to the illustrated embodiment, the first conductivity type is n-type, the second conductivity type is p-type, the first electrode structure 310 is a source electrode and the second electrode structure 320 is a drain electrode. According to other embodiments, the first conductivity type is p-type and the second conductivity type is n-type.

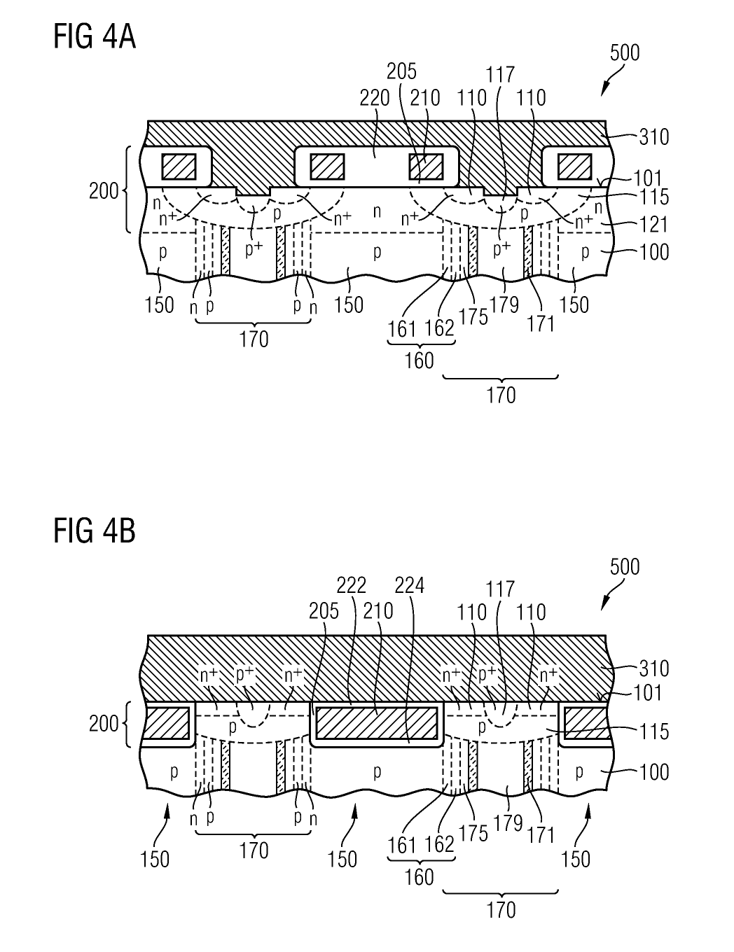

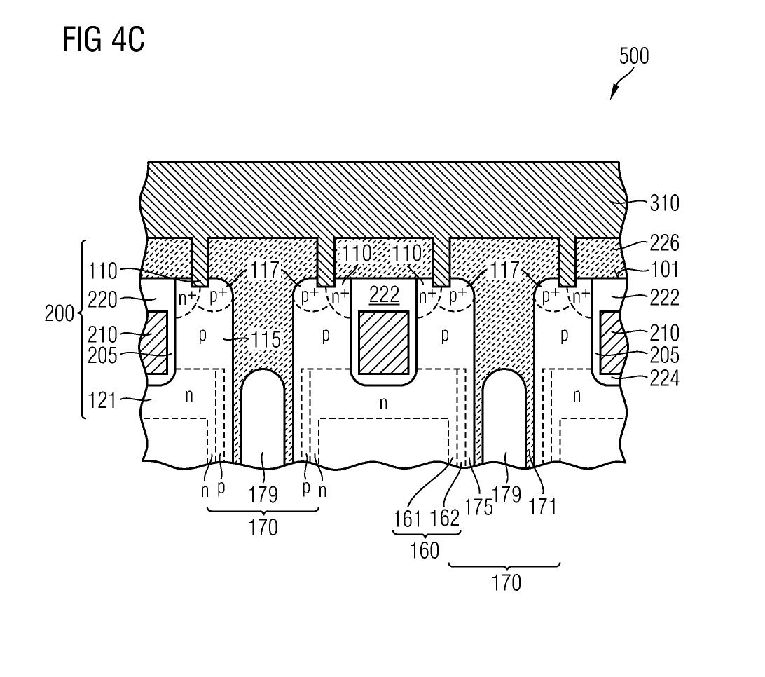

FIGS. 4A to 4C illustrate embodiments of the control structure 200 for IGFETs and IGBTs. The control structures 200 are based on IGFET cells with the first compensation layer 161 of the compensation structure 160 forming part of the drain structure of the respective IGFET cell.

FIG. 4A shows a control structure 200 including planar FET cells with gate electrodes 210 provided outside the semiconductor portion 100. The semiconductor portion 100 includes body zones 115 of the second conductivity type extending from the first surface 101 into the semiconductor portion 100. The body zones 115 may be formed in a semiconductor body that is provided in the vertical projection of the compensation trenches 170 between the compensation trenches 170 and the first surface 101. For example, the semiconductor bodies may be formed by overgrowing previously formed compensation trenches 170 by epitaxy or by locally annealing a deposited semiconductor layer, for example by using a laser.

The body zones 115 may have a mean net impurity concentration of at least 1×10¹⁵ cm⁻³ and at most 1×10¹⁸ cm⁻³. Each body zone 115 may be structurally connected to the p-type compensation layer 162 of the compensation structure 160 assigned to one compensation trench 170. In each body zone 115, one or two source zones 110 of the first conductivity type are formed as wells embedded in the body zones 115 and extend from the first surface 101 into the base zones 115. Heavily doped contact zones 117 may extend between neighboring source zones 110 into the body zones 115 for providing an ohmic contact between the first electrode structure 310 and the body zones 115.

In each IGFET cell, a gate dielectric 205 capacitively couples a gate electrode 210 with a channel portion of the body zone 115 such that a potential applied to the gate electrode 210 controls the charge carrier distribution in the channel portion between the source zones 110 and link zones 121 of the first conductivity type. The link zones 121 are formed in the mesa regions 150 along the first surface 101 and structurally connected with the n-type compensation layer 161. The link zones 121 may directly adjoin the first surface 101 such that in the conductive state of an IGFET cell, a conductive channel formed in the channel portion 115 along the gate dielectric 205 connects the source zone 110 with the n-type compensation layer 161 through the link zone 121.

A dielectric structure 220 encapsulates the gate electrodes 210 and dielectrically insulates the gate electrodes 210 from the first electrode structure 310. The first electrode structure 310 is electrically connected to the source zones 110 and the contact zones 117 through openings between the insulated gate electrode structures 210.

FIG. 4B corresponds to the control structure 200 of FIG. 4A with respect to the formation of the body zones 115, the contact zones 117 and the source zones 110 in a semiconductor body in the vertical projection of the compensation trenches 170. Different than in FIG. 4A, buried gate electrodes 210 are formed in gate trenches extending between neighboring compensation trenches 170 into the semiconductor portion 100. The gate trenches may have the same width as the mesa regions 150 between the compensation trenches 170. Channel portions extend through the body zones 115 in a vertical direction along vertical gate dielectrics 205. In each IGFET cell, the channel may be formed between the source zone 110 and the n-type compensation layer 161 or between the source zone 110 and a link zone, which has the first conductivity type and which is structurally connected with the first compensation layer 161.

A first dielectric structure 222 dielectrically insulates the gate electrode 210 from the first electrode structure 310 and a second dielectric structure 224 dielectrically insulates the gate electrode 210 from the mesa regions 150.

FIG. 4C illustrates a control structure 200 with IGFET cells whose gate electrodes 210, body zones 115 and source zones 110 are formed in the mesa regions 150 between the compensation trenches 170. The gate electrodes 210 are formed in gate trenches extending from the first surface 101 into the mesa regions 150. For each IGFET cell, a first dielectric structure 222 separates the gate electrode 210 from the source zones 110, which extend from the first surface 101 along the gate trench into the mesa region 150. A second dielectric structure 224 separates the gate electrode from a link zone 121 of the first conductivity type, which is formed in the mesa region 150 and structurally connected to the n-type compensation layer 161. The body zone 110 is formed in a vertical section of the mesa region 150 corresponding to the vertical extension of the gate electrodes 210 and is structurally connected to the p-type compensation layer 162.

A third dielectric structure 226 dielectrically insulates the first electrode structure 310 from the mesa regions 150 and may form plugs in the uppermost portion of the compensation trenches 170. Each plug seals an air gap 179 formed in a central portion of the corresponding compensation trench 170 and protects sidewalls of the body zones 115 directly adjoining the compensation trench 170.

Each of the control structures 200 of FIGS. 4A to 4C may be combined with the semiconductor devices 500 as illustrated in the previous and the following Figures.

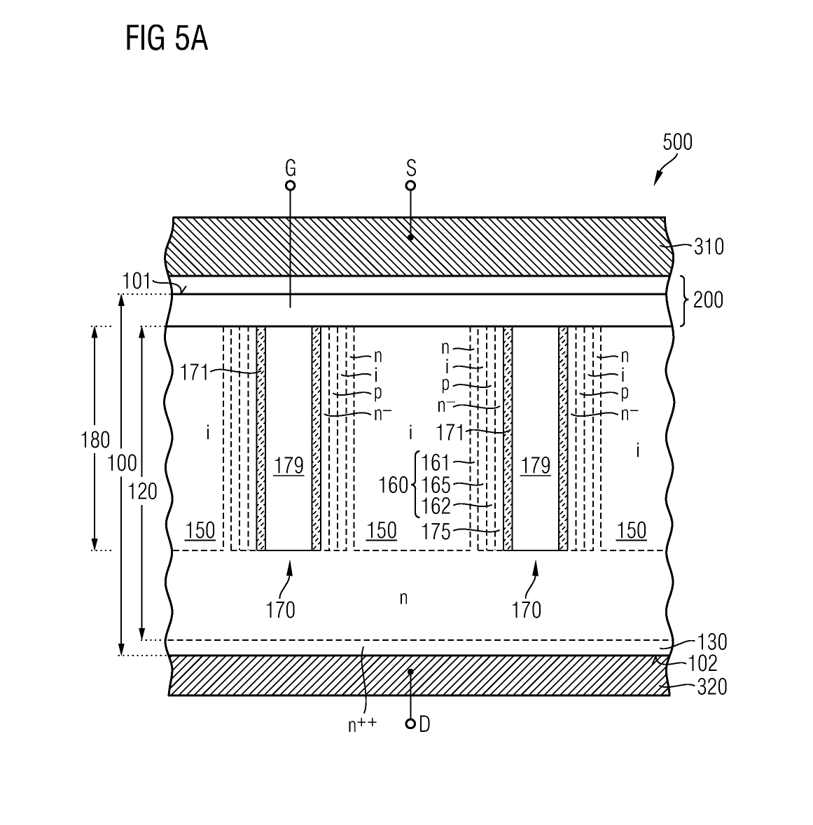

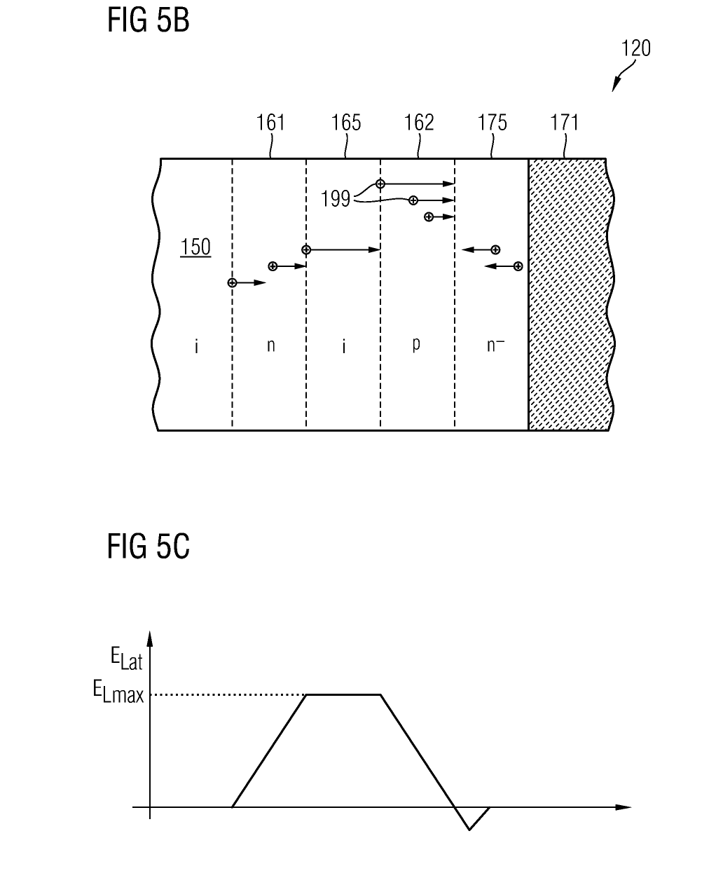

FIGS. 5A to 5C refer to an embodiment providing a lightly n-doped intermediate layer 175. In addition, the compensation structure 160 includes an intrinsic layer 165 between the n-type compensation layer 161 and the p-type compensation layer 162. The intrinsic layer 165 bars the p-type impurities from diffusing from the p-type compensation layer 162 into the n-type compensation layer 161 and the n-type impurities from diffusing from the n-type impurity layer 161 into the p-type impurity layer 162 during process steps requiring a temperature budget supporting a diffusion of the impurities.

As shown in FIG. 5C a lateral electric field generated at the pn junction between the p-type compensation layer 162 and the intermediate layer 175 is opposed to that between the n-type compensation layer 161 and the p-type compensation layer 162. The lateral electric field in the intermediate layer 175 accelerates holes 199 in a direction away from the dielectric layer 171 as shown in FIG. 5B. In the avalanche case, a hole current is kept off from the interface between the intermediate layer 175 and the dielectric layer 171.

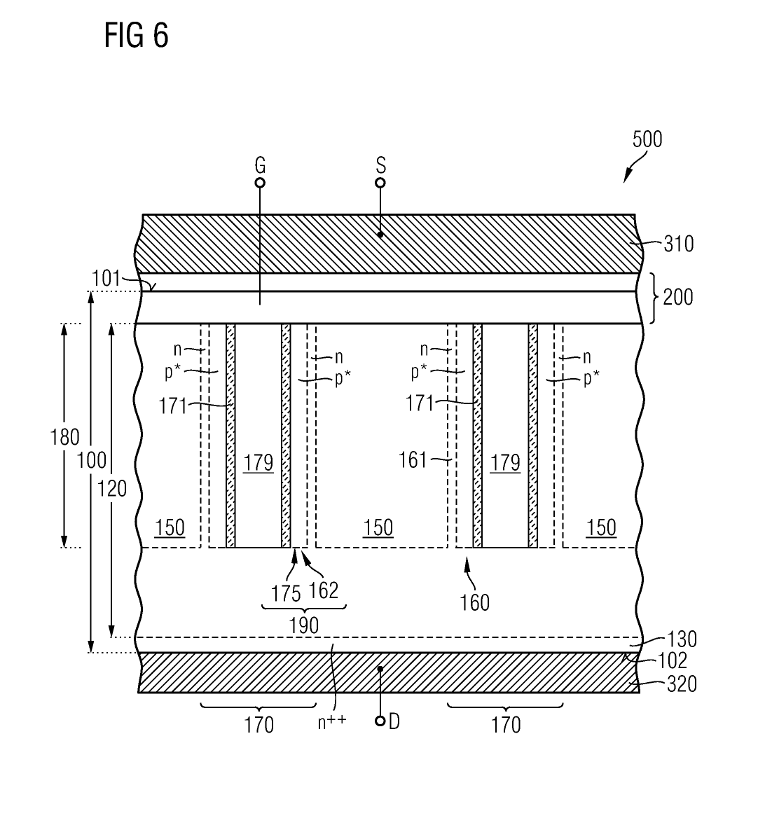

According to the embodiment of FIG. 6 the intermediate layer 175 is a part of a p-type layer 190, comprising also the p-type compensation layer 162. The impurity concentration p in the p-type layer 190 decreases to a value at most ten times the intrinsic charge carrier density, e.g. zero, with decreasing distance to the dielectric layer 171.

According to an embodiment, the p-type impurities in the p-type layer 190 are boron B atoms. Along an interface between a semiconductor material and a silicon oxide, boron atoms tend to diffuse into the silicon oxide to form a boron-doped silicon oxide material. The diffusion of boron results in a graded impurity profile at least in the intermediate layer portion of the p-type layer 190. As a result, the interface between the semiconductor material and the dielectric layer 171 remains free or approximately free of any hole current such that approximately no holes are incorporated into the dielectric layer 171.

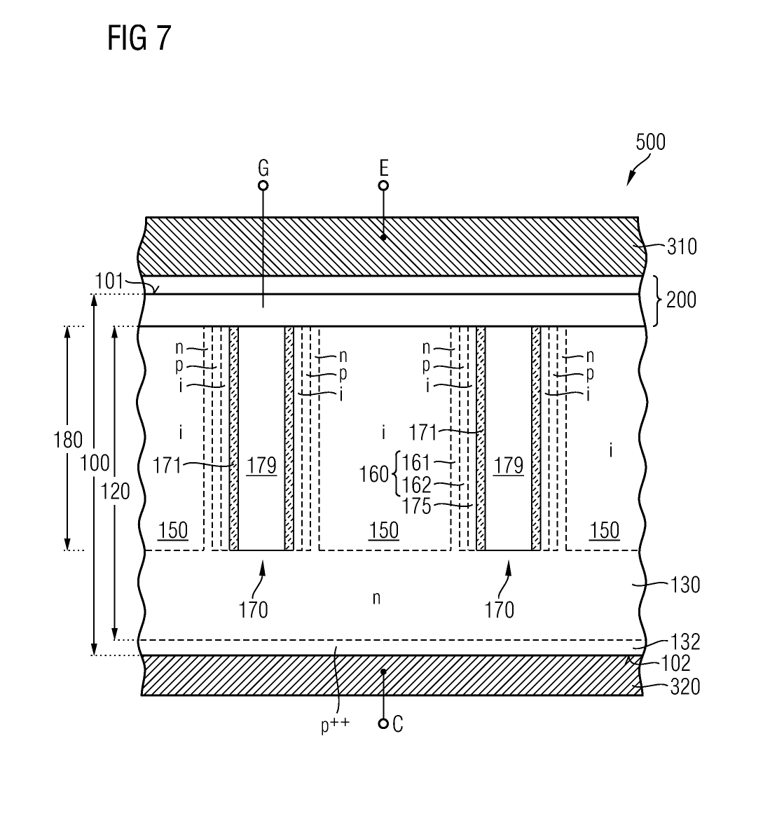

FIG. 7 shows a semiconductor device 500 of the IGBT type with a collector layer 132 having the second conductivity type formed along the second surface 102 and directly adjoining the second electrode structure 320, which is electrically coupled to a collector terminal C. The first electrode structure 310 is electrically coupled to an emitter terminal E. The first conductivity type is n-type and the second conductivity type p-type according to this embodiment.

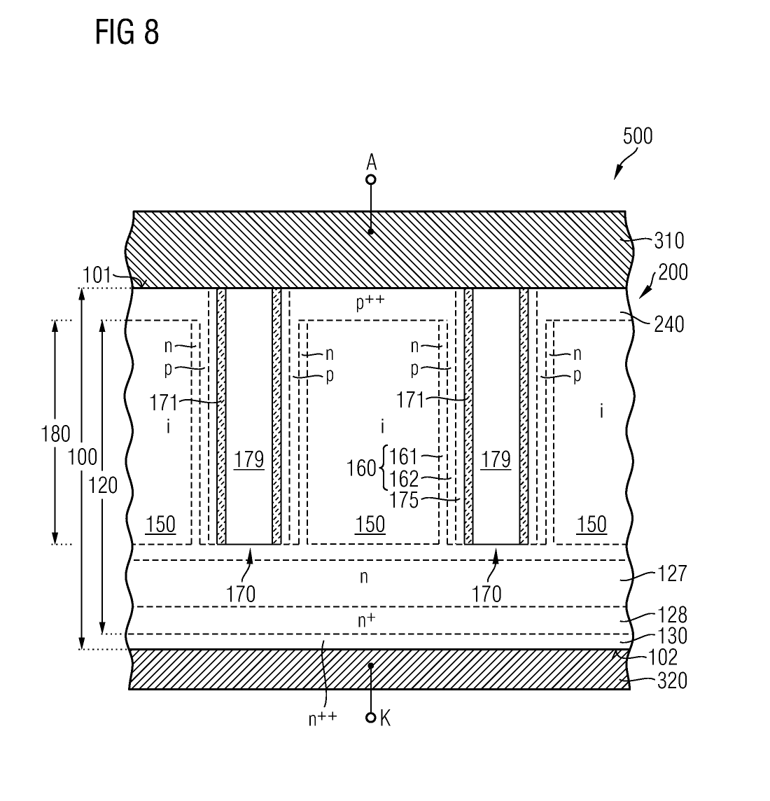

FIG. 8 refers to a semiconductor device 500 providing a semiconductor diode. The control structure 200 is an electrode zone 240 of the second conductivity type formed in sections of the mesa regions 150 directly adjoining the first surface 101 and structurally connected with the compensation layer of the same conductivity type.

In the illustrated embodiment, the first conductivity type is n-type, the second conductivity type is p-type, the electrode zone 240 provides an anode zone connected with the p-type compensation layer 162, the first electrode structure 310 provides an anode electrode electrically coupled to an anode terminal A, the impurity layer 130 provides a cathode zone connected with the n-type compensation layer 161, and the second electrode structure 320 provides a cathode electrode electrically coupled to a cathode terminal K.

According to another embodiment, the first conductivity type is p-type, the second conductivity type is n-type, the electrode zone 240 provides a cathode zone connected with the n-type compensation layer 161, the first electrode structure provides a cathode electrode electrically coupled to a cathode terminal K, the impurity layer 130 provides an anode zone connected with the p-type compensation layer 161, and the second electrode structure 320 provides an anode electrode electrically coupled to an anode terminal A.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A super junction semiconductor device, comprising:
a layered compensation structure comprising an n-type compensation layer and a p-type compensation layer;
a dielectric layer facing the p-type layer; and
an intermediate layer interposed between the dielectric layer and the p-type compensation layer, the layered compensation structure and the intermediate layer being disposed such that when a reverse blocking voltage is applied between the n-type and p-type compensation layers, holes accelerated in the direction of the dielectric layer have insufficient energy to be absorbed and incorporated into the dielectric material.

2. The super junction semiconductor device according to claim 1, wherein at least a portion of the intermediate layer directly adjoining the dielectric layer is free of an electric field accelerating holes in the direction of the dielectric layer when a reverse blocking voltage is applied between the n-type and p-type compensation layers.

3. The super junction semiconductor device according to claim 1, wherein the intermediate layer is an intrinsic semiconductor layer.

4. The super junction semiconductor device according to claim 1, wherein the intermediate layer is an n-type semiconductor layer with a lateral area charge density at most a tenth of the corresponding lateral area charge density in the n-type compensation layer.

5. The super junction semiconductor device according to claim 1, wherein:
the intermediate layer contains p-type impurities;
a maximum impurity concentration in the intermediate layer is not higher than a minimum impurity concentration in the p-type compensation layer; and
the impurity concentration in the intermediate layer continuously decreases with decreasing distance to the dielectric layer.

6. The super junction semiconductor device according to claim 5, wherein the p-type impurities are boron atoms.

7. The super junction semiconductor device according to claim 5, wherein the dielectric layer contains doped silicon oxide.

8. The super junction semiconductor device according to claim 1, wherein a minimum thickness of the intermediate layer is 5 nm.

9. The super junction semiconductor device according to claim 1, wherein a maximum thickness of the intermediate layer is 500 nm.

10. The super junction semiconductor device according to claim 1, wherein the area charge density in the p-type layer is equal to the area charge density in the n-type layer or deviates from the area charge density in the n-type layer by at most 10%.

11. The super junction semiconductor device according to claim 1, wherein the compensation structure includes an intrinsic layer separating the n-type layer and the p-type layer.

12. The super junction semiconductor device according to claim 1, wherein the layered compensation structure directly adjoins mesa sidewalls of mesa regions of a semiconductor portion, the mesa sidewalls extending in a direction tilted to a first surface of the semiconductor portion between the first surface and an impurity layer of a first conductivity type.

13. The super junction semiconductor device according to claim 12, wherein the layered compensation structure lines a compensation trench extending between two of the mesa regions between the first surface and the impurity layer.

14. The super junction semiconductor device according to claim 13, wherein the layered compensation structure lines a plurality of compensation trenches.

15. The super junction semiconductor device according to claim 13, wherein a total thickness of the dielectric layer, the intermediate layer, and the compensation structure is less than half of a lateral width of the compensation trench.

16. The super junction semiconductor device according to claim 13, wherein the compensation structure and the dielectric layer leave a void in at least a portion of each of the compensation trenches.

17. The super junction semiconductor device according to claim 12, wherein a net impurity concentration in the mesa regions is at most 1×10¹⁵ cm⁻³.

18. The super junction semiconductor device according to claim 12, further comprising:
a control structure comprising body zones of the second conductivity type structurally connected with the p-type compensation layer and source zones of the first conductivity type structurally separated from the p-type compensation layer by the body zones; and
gate electrodes, each gate electrode being capacitively coupled to one of the body zones.

19. The super junction semiconductor device according to claim 18, wherein the body zones are provided in a vertical projection of the compensation trenches.

20. The super junction semiconductor device according to claim 18, wherein the gate electrodes are provided in gate trenches extending from the first surface into the mesa regions.
